(19) United States
(12) Patent Application Publication
(10) Pub. No.: US 2022/0328387 A1
(43) Pub. Date: Oct. 13, 2022

(54) PACKAGE CARRIER AND MANUFACTURING METHOD THEREOF

(71) Applicant: Unimicron Technology Corp., Taoyuan City (TW)

(72) Inventors: John Hon-Shing Lau, Taoyuan City (TW); Cheng-Ta Ko, Taipei City (TW); Pu-Ju Lin, Hsinchu City (TW); Kai-Ming Yang, Hsinchu County (TW); Chi-Hai Kuo, Taoyuan City (TW); Chia-Yu Peng, Taoyuan City (TW); Tzyy-Jang Tseng, Taoyuan City (TW)

(73) Assignee: Unimicron Technology Corp., Taoyuan City (TW)

(21) Appl. No.: 17/232,128

(22) Filed: Apr. 15, 2021

(30) Foreign Application Priority Data
Apr. 8, 2021 (TW) 110112683

(51) Int. Cl. H01L 23/498; H01L 21/48; H01L 21/683

(52) U.S. Cl. CPC H01L 23/49822; H01L 23/49838; H01L 21/4857; H01L 21/6835; H01L 23/49816; H01L 2221/68345; H01L 2221/68359; H01L 24/16

(57) ABSTRACT

A package carrier includes a first redistribution layer having a first upper surface and a first lower surface and including a plurality of first redistribution circuits, a plurality of conductive through holes, a plurality of photoimageable dielectric layers, and a plurality of chip pads and a second redistribution layer disposed on the first upper surface of the first redistribution layer. The second redistribution layer has a second upper surface and a second lower surface aligned with and directly connected to the first upper surface of the first redistribution layer and includes a plurality of second redistribution circuits, a plurality of conductive structures, a plurality of Ajinomoto build-up Film (ABF) layers, and a plurality of solder ball pads. A line width and a line pitch of each of the first redistribution circuits are smaller than a line width and a line pitch of each of the second redistribution circuits.

### CROSS-REFERENCE TO RELATED APPLICATION

This application claims the priority benefit of Taiwan application no. 110112683, filed on Apr. 8, 2021. The entirety of the above-mentioned patent application is hereby incorporated by reference herein and made a part of this specification.

### BACKGROUND

### Technical Field

The disclosure relates to a semiconductor structure and a manufacturing method thereof; particularly, the disclosure relates to a package carrier and a manufacturing method thereof.

### Description of Related Art

Regarding package structures of embedded High Density Films (eHDF), since the high density films in the structures adopt the wafer manufacturing process, which is only applicable to single-sided circuit build-up structures, and requires to be accompanied with semiconductor equipment, the requirements of high output and low costs cannot be fulfilled. On the other hand, since build-up of organic substrates is limited to single-sided build-up structures, substrate warpage in the process cannot be effectively solved in spite of a temporary wafer substrate that supports the overall structure. Moreover, the workflow of surface treatment at the chip end can only be performed after disassembling the substrates, and thus is only applicable to the existing flexible board packaging process, instead of being widely applied to other packaging processes, such as a carrier manufacturing process. Besides, since partially embedded photoimageable dielectric layer structures are anisotropic structures, it is relatively difficult to control expansion and contraction in the X direction and the Y direction.

### SUMMARY

The disclosure provides a package carrier and a manufacturing method thereof, which achieves manufacture of double-sided circuit build-up structures, effectively solves substrate warpage in the manufacturing process, and increases throughput and reduces production costs.

According to the disclosure, a package carrier includes a first redistribution layer and a second redistribution layer. The first redistribution layer has a first upper surface and a first lower surface opposite to each other. The first redistribution layer includes a plurality of first redistribution circuits, a plurality of conductive through holes, a plurality of photoimageable dielectric layers, and a plurality of chip pads. The first redistribution circuits are alternately stacked with the photoimageable dielectric layers, the conductive through holes electrically connects adjacent two of the first redistribution circuits, and the chip pads are located on the first lower surface and are electrically connected to the first redistribution circuits through the conductive through holes. The second redistribution layer is disposed on the first upper surface of the first redistribution layer, and has a second upper surface and a second lower surface opposite to each other. The second redistribution layer includes a plurality of second redistribution circuits, a plurality of conductive structures, a plurality of Ajinomoto build-up film (ABF) layers, and a plurality of solder ball pads. The second redistribution circuits are alternately stacked with the Ajinomoto build-up film layers, and the conductive structures electrically connects adjacent two of the second redistribution circuits and a closest one of the first redistribution circuits to the second redistribution circuits. One of the Ajinomoto build-up film layers has the second upper surface and exposes the solder ball pads. The second lower surface of the second redistribution layer is aligned with and directly connected to the first upper surface of the first redistribution layer. A line width and a line pitch of each of the first redistribution circuits are smaller than a line width and a line pitch of each of the second redistribution circuits.

In an embodiment of the disclosure, the line width and the line pitch of each of the first redistribution circuits each range from 2 μm to 10 μm.

In an embodiment of the disclosure, the line width and the line pitch of each of the second redistribution circuits each range from 15 μm to 35 μm.

In an embodiment of the disclosure, the first redistribution circuits include a first circuit layer and a plurality of second circuit layers. The photoimageable dielectric layers include a first dielectric layer, at least one second dielectric layer, and a third dielectric layer. The first dielectric layer covers the first circuit layer, and the first dielectric layer and the first circuit layer define the first upper surface. The second dielectric layer and the third dielectric layer cover the second circuit layers. In addition, the chip pads are located on the third dielectric layer, and the third dielectric layer has the first lower surface.

In an embodiment of the disclosure, the second redistribution circuits include a third circuit layer, at least one fourth circuit layer, and a fifth circuit layer. The Ajinomoto build-up film layers include a first film layer, at least one second film layer, and a third film layer. The conductive structures include a plurality of first conductive structures and a plurality of second conductive structures. The first film layer includes a plurality of first openings, and the first conductive structures are respectively located in the first openings and respectively cover inner walls of the first openings. The first film layer and the first conductive structures define the second lower surface. The third circuit layer is located on the first film layer and connected to the first conductive structures. The first conductive structures electrically connect the first circuit layer with the third circuit layer. The fourth circuit layer is located on the second film layer. The second film layer includes a plurality of second openings. The second conductive structures are respectively located in the second openings, respectively cover inner walls of the second openings, and electrically connects the third circuit layer with the fourth circuit layer and the fourth circuit layer with the fifth circuit layer. The third film layer has the second upper surface and includes a plurality of third openings, and the third openings expose a portion of the fifth circuit layer and define the solder ball pads.

In an embodiment of the disclosure, a size of each of the chip pads is smaller than a size of each of the solder ball pads.

In an embodiment of the disclosure, the photoimageable dielectric layers each have a plurality of openings, and the conductive through holes respectively fill the openings and are connected to the first redistribution circuits.

In an embodiment of the disclosure, an extension direction of each of the conductive through holes is opposite to an extension direction of each of the conductive structures.

In an embodiment of the disclosure, a thickness of the first redistribution layer is smaller than a thickness of the second redistribution layer.

According to the disclosure, a manufacturing method of a package carrier includes the following steps. First, two redistribution circuit units are formed. Each of the first redistribution circuit units includes a first carrier, a first redistribution layer, and a protective layer. The first redistribution layer is located between the first carrier and the protective layer. The first redistribution layer has a first upper surface and a first lower surface opposite to each other, and includes a plurality of first redistribution circuits, a plurality of conductive through holes, a plurality of photoimageable dielectric layers, and a plurality of chip pads. The first redistribution circuits are alternately stacked with the photoimageable dielectric layers, and the conductive through holes electrically connect adjacent two of the first redistribution circuits. The chip pads are located on the first lower surface and are electrically connected to the first redistribution circuits through the conductive through holes. The first upper surface is in direct contact with the first carrier, and the protective layer covers the first lower surface and the chip pads. Also, a second carrier is provided between the two first redistribution circuit units. The second carrier is in direct contact with the protective layer of each of the first redistribution circuit units. Next, the first carrier is removed and the first upper surface of the first redistribution layer is exposed in each of the first redistribution circuit units. Then, a second redistribution layer is formed on the first upper surface of each of the first redistribution layers. The second redistribution layer has a second upper surface and a second lower surface opposite to each other, and includes a plurality of second redistribution circuits, a plurality of conductive structures, a plurality of Ajinomoto build-up film layers, and a plurality of solder ball pads. The second redistribution circuits are alternately stacked with the Ajinomoto build-up film layers. The conductive structures electrically connect adjacent two of the second redistribution circuits and a closest one of the first redistribution circuits to the second redistribution circuits. One of the Ajinomoto build-up film layers has the second upper surface and exposes the solder ball pads. The second lower surface of the second redistribution layer is aligned with and directly connected to the first upper surface of the first redistribution layer. A line width and a line pitch of each of the first redistribution circuits are smaller than a line width and a line pitch of each of the second redistribution circuits. Lastly, the second carrier and the protective layer of each of the first redistribution circuit units are removed, and the first lower surface and the chip pads of the first redistribution layer are exposed.

In an embodiment of the disclosure, the step where each of the first redistribution circuit units is formed includes the following steps. Firstly, the first redistribution layer is formed on the first carrier. The first carrier includes a glass substrate, a sacrificial layer, and a seed layer. The sacrificial layer is located between the glass substrate and the seed layer, and the first upper surface of the first redistribution layer is in direct contact with the seed layer. Also, the protective layer is formed on the first lower surface of the first redistribution layer, and covers the chip pads.

In an embodiment of the disclosure, the second carrier includes a substrate and two double-sided adhesive layers located on two opposite sides of the substrate. Each of the double-sided adhesive layers is located between the substrate and the protective layer of each of the redistribution circuit units.

In an embodiment of the disclosure, the first redistribution circuits further include a first circuit layer and a plurality of second circuit layers. The photoimageable dielectric layers include a first dielectric layer, at least one second dielectric layer, and a third dielectric layer. The first dielectric layer covers the first circuit layer, and the first dielectric layer and the first circuit layer define the first upper surface. The second dielectric layer and the third dielectric layer cover the second circuit layers, the chip pads are located on the third dielectric layer, and the third dielectric layer has the first lower surface.

In an embodiment of the disclosure, the second redistribution circuits include a third circuit layer, at least one fourth circuit layer, and a fifth circuit layer. The Ajinomoto build-up film layers include a first film layer, at least one second film layer, and a third film layer. The conductive structures include a plurality of first conductive structures and a plurality of second conductive structures. The first film layer includes a plurality of first openings, and the first conductive structures are respectively located in the first openings and respectively cover inner walls of the first openings. The first film layer and the first conductive structures define the second lower surface. The third circuit layer is located on the first film layer and connected to the first conductive structures. The first conductive structures electrically connect the first circuit layer with the third circuit layer. The fourth circuit layer is located on the second film layer. The second film layer includes a plurality of second openings. The second conductive structures are respectively located in the second openings, respectively cover inner walls of the second openings, and electrically connects the third circuit layer with the fourth circuit layer and the fourth circuit layer with the fifth circuit layer. The third film layer has the second upper surface and includes a plurality of third openings. The third openings expose a portion of the fifth circuit layer and define the solder ball pads.

In an embodiment of the disclosure, the line width and the line pitch of each of the first redistribution circuits each range from 2 μm to 10 μm.

In an embodiment of the disclosure, the line width and the line pitch of each of the second redistribution circuits each range from 15 μm to 35 μm.

In an embodiment of the disclosure, a size of each of the chip pads is smaller than a size of each of the solder ball pads.

In an embodiment of the disclosure, an extension direction of each of the conductive through holes is opposite to an extension direction of each of the conductive structures.

In an embodiment of the disclosure, each of the second redistribution circuits is formed at the same time with each of the conductive structures.

In an embodiment of the disclosure, a thickness of the first redistribution layer is smaller than a thickness of the second redistribution layer.

Based on the foregoing, in the disclosure, the first redistribution layer with the smaller line width and line pitch is firstly manufactured on the first carrier, and then transferred onto the second carrier for the double-sided manufacture of the second redistribution layer with the larger line width line pitch. After that, the second carrier is removed to complete the manufacture of two package carriers. Thereby, the package carrier with a double-sided circuit build-up structure can be manufactured. In addition, with the double-sided manufacture, substrate warpage in the manufacturing process is effectively solved, throughput is increased, and production costs are reduced. Besides, since the first redistribution layer is an entire-surface structure instead of a partial structure, compensation for the expansion and contraction in the X and Y directions is effectively performed, and the size of the package carrier is easily controlled.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A to FIG. 1E are schematic cross-sectional views of a manufacturing method of a package carrier according to an embodiment of the disclosure.

FIG. 2 is a schematic cross-sectional view of chips and solder balls being packaged on the package carrier of FIG. 1E.

### DESCRIPTION OF THE EMBODIMENTS

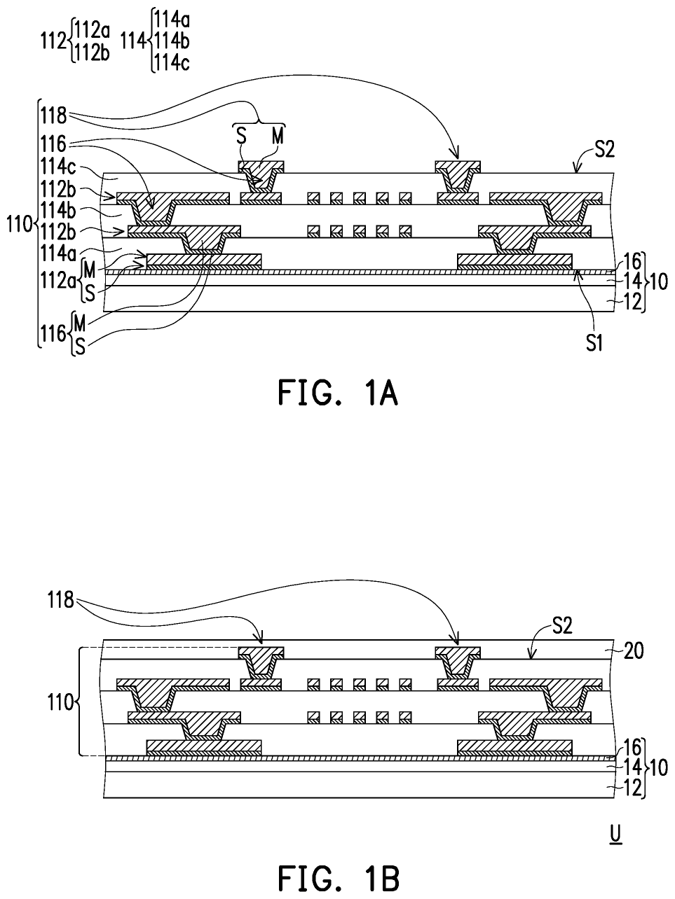

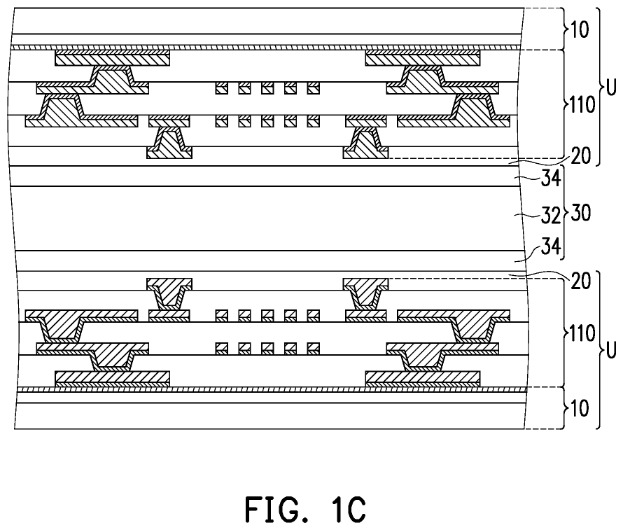

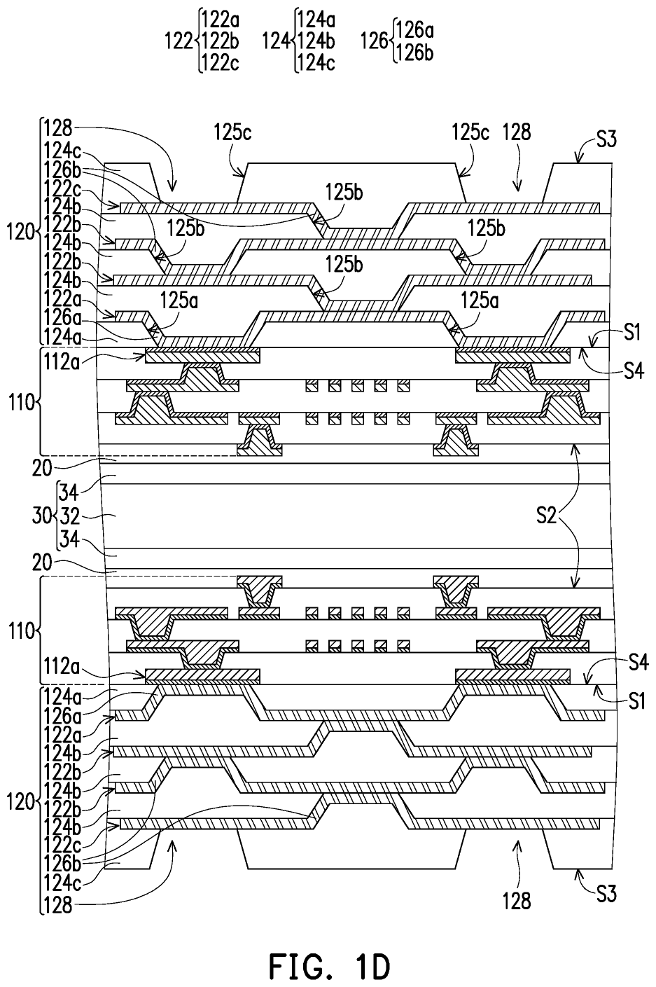

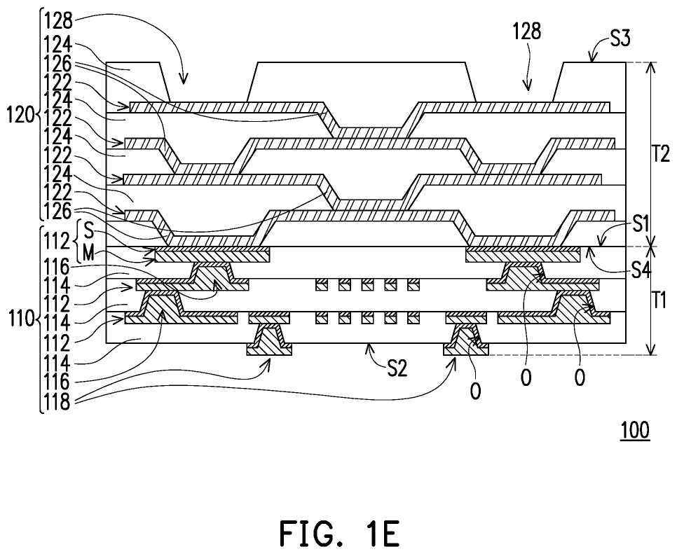

FIG. 1A to FIG. 1E are schematic cross-sectional views of a manufacturing method of a package carrier according to an embodiment of the disclosure. Regarding the manufacturing method of the package carrier of this embodiment, firstly, with reference to FIG. 1B, a first redistribution circuit unit U is formed, where the first redistribution circuit unit U each includes a first carrier 10, a first redistribution layer 110, and a protective layer 20.

To be specific, with reference to FIG. 1A, the step of forming the first redistribution circuit unit U includes first forming the first redistribution layer 110 on the first carrier 10. The first carrier 10 includes a glass substrate 12, a sacrificial layer 14, and a seed layer 16, where the sacrificial layer 14 is located between the glass substrate 12 and the seed layer 16. Herein, a material of the sacrificial layer 14 includes, for example, a material suitable for laser debonding or thermal debonding, and a material of the seed layer 16 includes, for example, titanium copper. The first redistribution layer 110 has a first upper surface S1 and a first lower surface S2 opposite to each other, and includes a plurality of first redistribution circuits 112, a plurality of photoimageable dielectric layers 114, a plurality of conductive through holes 116, and a plurality of chip pads 118. The first redistribution circuits 112 are alternately stacked with the photoimageable dielectric layers 114, and the conductive through holes 116 electrically connect adjacent two of the first redistribution circuits 112. The photoimageable dielectric layer 114 has a plurality of blind holes, each of the blind holes extends in a direction from being away from the seed layer 16 to being close to the seed layer 16, and a metal material layer is filled in the blind holes to form the through holes 116. The chip pads 118 are located on the first lower surface S2 and are electrically connected to the first redistribution circuits 112 through the conductive through holes 116. Herein, the first upper surface S1 is in direct contact with the first carrier 10, and the first upper surface S1 of the first redistribution layer 110 is in direct contact with the seed layer 16.

Furthermore, with further reference to FIG. 1A, in this embodiment, the first redistribution circuits 112 further include a first circuit layer 112a and a plurality of second circuit layers 112b. The photoimageable dielectric layers 114 include a first dielectric layer 114a, at least one second dielectric layer 114b, and a third dielectric layer 114c. The first dielectric layer 114a covers the first circuit layer 112a, and the first dielectric layer 114a and the first circuit layer 112a define the first upper surface S1. The second dielectric layer 114b and the third dielectric layer 114c cover the second circuit layers 112b, the chip pads 118 are located on the third dielectric layer 114c, and the third dielectric layer 114c has the first lower surface S2. Preferably, a line width and a line pitch of each of the first redistribution circuits 112 each range from, for example, 2 μm to 10 μm. For example, the line widths and the line pitches of the first redistribution circuits 112 are, for example, 2 μm, 5 μm, and 10 μm, namely the first circuit layer 112a and the second circuit layers 112b are thin circuit layers. Herein, the first redistribution circuits 112, the conductive through holes 116, and the chip pads 118 each include a seed layer S and a metal layer M located on the seed layer S. That is to say, the first redistribution circuits 112, the conductive through holes 116, and the chip pads 118 are each a two-layer structure, formed of the seed layer S and the metal layer M.

Next, with further reference to FIG. 1B, the protective layer 20 is formed on the first lower surface S2 of the first redistribution layer 110 and covers the chip pads 118. The protective layer 20 is formed, for example, by lamination. At this time, the first redistribution layer 110 is located between the first carrier 10 and the protective layer 20, and the protective layer 20 covers the first lower surface S2 and the chip pads 118. Herein, a material of the protective layer 20 includes, for example, an Ajinomoto build-up film (ABF). At this point, the manufacture of the first redistribution circuit unit U is completed.

Next, with reference to FIG. 1C, a second carrier 30 is provided between two first redistribution circuit units U, where the second carrier 30 is in direct contact with the protective layer 20 of each of the first redistribution circuit units U. Furthermore, in this embodiment, the second carrier 30 includes a substrate 32 and two double-sided adhesive layers 34 on two opposite sides of the substrate 32. Each of the double-sided adhesive layers 34 is located between the substrate 32 and the protective layer 20 of each of the redistribution circuit units U. Herein, the substrate 32 is, for example, a temporary substrate without circuits, and the double-sided adhesive layers 34 may also be replaced with mechanical debond Cu.

After that, with reference to FIG. 1C and FIG. 1D together, the first carrier 10 is removed and the first upper surface S1 of the first redistribution layer 110 is exposed in each of the first redistribution circuit units U. Herein, the first carrier 10 is removed by first removing the glass substrate 12 and the sacrificial layer 14, and then etching the seed layer 16 to expose the first upper surface S1 of the first redistribution layer 110.

Next, with further reference to FIG. 1D, a second redistribution layer 120 is formed on the first upper surface S1 of each of the first redistribution layers 110. The second redistribution layer 120 has a second upper surface S3 and a second lower surface S4 opposite to each other, and includes a plurality of second redistribution circuits 122, a plurality of Ajinomoto build-up film layers 124, a plurality of conductive structures 126, and a plurality of solder ball pads 128. The second redistribution circuits 122 are alternately stacked with the Ajinomoto build-up film layers 124. The conductive structures 126 electrically connect adjacent two of the second redistribution circuits 122 and a closest one of the first redistribution circuits 112 to the second redistribution circuits 122. One of the Ajinomoto build-up film layers 124 has the second upper surface S3 and exposes the solder ball pads 128.

Furthermore, in this embodiment, the second redistribution circuits 122 includes a third circuit layer 122a, at least one fourth circuit layer 122b, and a fifth circuit layer 122c. The Ajinomoto build-up film layers 124 include a first film layer 124a, at least one second film layer 124b, and a third film layer 124c. The conductive structures 126 include a plurality of first conductive structures 126a and a plurality of second conductive structures 126b. The first film layer 124a includes a plurality of first openings 125a, and the first conductive structures 126a are respectively located in the first openings 125a and respectively cover inner walls of the first openings 125a. The first film layer 124a and the first conductive structures 126a define the second lower surface S4. Particularly, the second lower surface S4 of the second redistribution layer 120 is aligned with and directly connected to the first upper surface S1 of the first redistribution layer 110. The third circuit layer 122a is located on the first film layer 124a and is connected to the first conductive structures 126a. The first conductive structures 126a electrically connects the first circuit layer 112a with the third circuit layer 122a. That is to say, among the first redistribution circuits 112, the first circuit layer 112a is closest to the third circuit layer 122a of the second redistribution circuits 122. The fourth circuit layer 122b is located on the second film layer 124b, and the second film layer 124b includes a plurality of second openings 125b. The second conductive structures 126b are respectively located in the second openings 125b, respectively covers inner walls of the second openings 125b, and electrically connects the third circuit layer 122a with the fourth circuit layer 122b, and the fourth circuit layer 122b with the fifth circuit layer 122c. The third film layer 124c has the second upper surface S3 and includes a plurality of third openings 125c, where the third openings 125c expose a portion of the fifth circuit layer 122c and define the solder ball pads 128. Herein, the second redistribution circuits 122 and the conductive structures 126 are formed at the same time, and line widths and line pitches of the second redistribution circuits 122 each range from, for example, 15 μm to 35 μm. For example, the line widths and line pitches of the second redistribution circuits 122 are, for example, 15 μm, 25 μm, and 35 μm, namely the third circuit layer 122a, the fourth circuit layer 122b, and the fifth circuit layer 122c are general circuit layers. An extension direction of the first opening 125a, the second opening 125b, and the third opening 125c is in a direction from being away from the first redistribution layer 110 to being close to the first redistribution layer 110. Therefore, when the first conductive structure 126a and the second conductive structure 126b are respectively disposed in the first opening 125a and the second opening 125b, an extension direction of the first conductive structure 126a and the second conductive structure 126b is also in a direction from being away from the first redistribution layer 110 to being close to the first redistribution layer 110.

Next, a surface treatment process is selectively performed on the solder ball pads 128. After that, with reference to FIG. 1D and FIG. 1E together, the second carrier 30 and the protective layer 20 are removed, and the first lower surface S2 and the chip pads 118 of the first redistribution layer 110 are exposed. Herein, the protective layer 20 is removed, for example, by plasma etching. At this point, the manufacture of a package carrier 100 is completed.

Structurally, with further reference to FIG. 1E, the package carrier 100 of this embodiment includes the first redistribution layer 110 and the second redistribution layer 120. The first redistribution layer 110 has the first upper surface S1 and the first lower surface S2 opposite to each other. The first redistribution layer 110 includes the first redistribution circuits 112, the photoimageable dielectric layers 114, the conductive through holes 116, and the chip pads 118. The first redistribution circuits 112 are alternately stacked with the photoimageable dielectric layers 114, and the conductive through holes 116 electrically connect adjacent two of the first redistribution circuits 112. The photoimageable dielectric layers 114 each have a plurality of openings O, where the conductive through holes 116 respectively fill the openings O and are connected to the first redistribution circuits 112. The chip pads 118 are located on the first lower surface S2 and are electrically connected to the first redistribution circuits 112 through the conductive through holes 116. Herein, the first redistribution circuits 112, the conductive through holes 116, and the chip pads 118 are each formed of the seed layer S and the metal layer M located on the seed layer S.

Moreover, the second redistribution layer 120 of this embodiment is disposed on the first upper surface S1 of the first redistribution layer 110, and has the second upper surface S3 and the second lower surface S4 opposite to each other. The second redistribution layer 120 includes the second redistribution circuits 122, the Ajinomoto build-up film layers 124, the conductive structures 126, and the solder ball pads 128. The second redistribution circuits 122 are alternately stacked with the Ajinomoto build-up film layers 124, and the conductive structures 126 electrically connects adjacent two of the second redistribution circuits 122 and the closest one of the first redistribution circuits 112 to the second redistribution circuits 122. One of the Ajinomoto build-up film layers 124 has the second upper surface S3 and exposes the solder ball pads 128.

Particularly, in this embodiment, the second lower surface S4 of the second redistribution layer 120 is aligned with and directly connected to the first upper surface S1 of the first redistribution layer 110. The line width and the line pitch of each of the first redistribution circuits 112 are smaller than the line width and the line pitch of each of the second redistribution circuits 122, namely the package carrier 100 of this embodiment has two redistribution layers with different line widths and line pitches. Preferably, the line width and the line pitch of each of the first redistribution circuits 112 each range from, for example, 2 μm to 10 μm, and the line width and the line pitch of each of the second redistribution circuits 122 each range from, for example, 15 μm to 35 μm. A size of each of the chip pads 118 is substantially smaller than a size of each of the solder ball pads 128. A thickness T1 of the first redistribution layer 110 is smaller than a thickness T2 of the second redistribution layer 120, where a thickness of each of the photoimageable dielectric layers 114 is, for example, smaller than or equal to 5 μm, and a thickness of each of the Ajinomoto build-up film layers 124 is, for example, greater than 10 μm. Besides, an extension direction of the conductive through holes 116 is opposite to an extension direction of the conductive structures 126.

Briefly speaking, in this embodiment, the first redistribution layer 110 with the smaller line width and line pitch is firstly manufactured on the first carrier 10, and then transferred onto the second carrier 30 for the double-sided manufacture of the second redistribution layer 120 with the larger line width line pitch. After that, the second carrier 30 is removed to complete the manufacture of two package carriers 100. Thereby, the package carrier 100 with a double-sided circuit build-up structure can be manufactured. In addition, with the double-sided manufacture, substrate warpage in the manufacturing process is effectively solved, throughput is increased, and production costs are reduced. Besides, since the first redistribution layer 110 is an entire-surface structure instead of a partial structure, compensation for the expansion and contraction in the X and Y directions is effectively performed, and the size of the package carrier 100 is easily controlled.

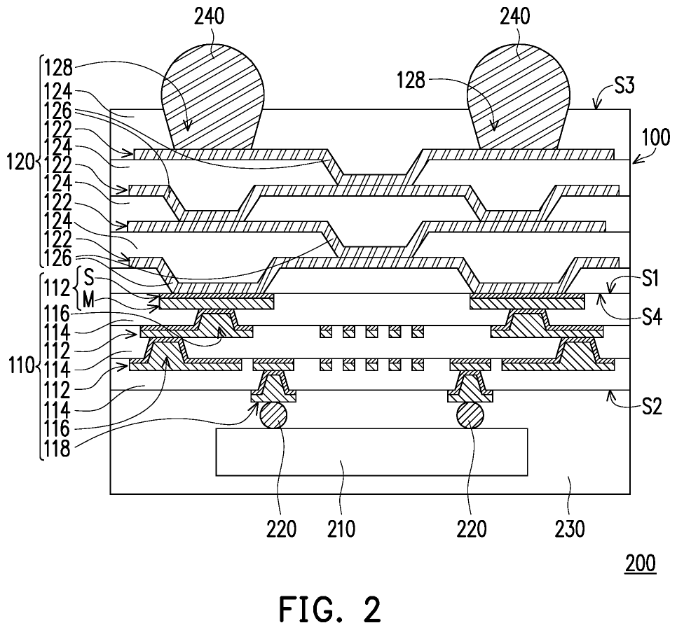

FIG. 2 is a schematic cross-sectional view of chips and solder balls being packaged on the package carrier of FIG. 1E. In application, with reference to FIG. 2, a chip 210 may be electrically connected to the chip pads 118 of the package carrier 100 through solder balls 220. An encapsulant 230 is disposed on the first lower surface S2 of the redistribution circuit layer 110 and covers the first lower surface S2, the chip pads 118, the chip 210, and the solder balls 220. Besides, solder balls 240 are disposed on the solder ball pads 128 of the package carrier 100 and protrude from the third surface S3 of the second redistribution layer 120 to be electrically connected to an external circuit (e.g., a circuit board). At this point, the manufacture of a package structure 200 is completed.

In summary of the foregoing, in the disclosure, the first redistribution layer with the smaller line width and line pitch is firstly manufactured on the first carrier, and then transferred onto the second carrier for the double-sided manufacture of the second redistribution layer with the larger line width line pitch. After that, the second carrier is removed to complete the manufacture of two package carriers. Thereby, the package carrier with a double-sided circuit build-up structure can be manufactured. In addition, with the double-sided manufacture, substrate warpage in the manufacturing process is effectively solved, throughput is increased, and production costs are reduced. Besides, since the first redistribution layer is an entire-surface structure instead of a partial structure, compensation for the expansion and contraction in the X and Y directions is effectively performed, and the size of the package carrier is easily controlled.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A package carrier, comprising:
a first redistribution layer having a first upper surface and a first lower surface opposite to each other, and the first redistribution layer comprising a plurality of first redistribution circuits, a plurality of conductive through holes, a plurality of photoimageable dielectric layers, and a plurality of chip pads, wherein the first redistribution circuits are alternately stacked with the photoimageable dielectric layers, the conductive through holes electrically connects adjacent two of the first redistribution circuits, and the chip pads are located on the first lower surface and are electrically connected to the first redistribution circuits through the conductive through holes; and
a second redistribution layer disposed on the first upper surface of the first redistribution layer, and having a second upper surface and a second lower surface opposite to each other, and the second redistribution layer comprising a plurality of second redistribution circuits, a plurality of conductive structures, a plurality of Ajinomoto build-up film layers, and a plurality of solder ball pads, wherein the second redistribution circuits are alternately stacked with the Ajinomoto build-up film layers, the conductive structures electrically connects adjacent two of the second redistribution circuits and a closest one of the first redistribution circuits to the second redistribution circuits, and one of the Ajinomoto build-up film layers has the second upper surface and exposes the solder ball pads, wherein the second lower surface of the second redistribution layer is aligned with and directly connected to the first upper surface of the first redistribution layer, and a line width and a line pitch of each of the first redistribution circuits are smaller than a line width and a line pitch of each of the second redistribution circuits.

2. The package carrier as described in claim 1, wherein the line width and the line pitch of each of the first redistribution circuits each range from 2 μm to 10 μm.

3. The package carrier as described in claim 1, wherein the line width and the line pitch of each of the second redistribution circuits each range from 15 μm to 35 μm.

4. The package carrier as described in claim 1, wherein the first redistribution circuits comprise a first circuit layer and a plurality of second circuit layers, and the photoimageable dielectric layers comprise a first dielectric layer, at least one second dielectric layer, and a third dielectric layer, wherein the first dielectric layer covers the first circuit layer, the first dielectric layer and the first circuit layer define the first upper surface, the at least one second dielectric layer and the third dielectric layer cover the second circuit layers, the chip pads are located on the third dielectric layer, and the third dielectric layer has the first lower surface.

5. The package carrier as described in claim 4, wherein the second redistribution circuits comprise a third circuit layer, at least one fourth circuit layer, and a fifth circuit layer, the Ajinomoto build-up film layers comprise a first film layer, at least one second film layer, and a third film layer, and the conductive structures comprise a plurality of first conductive structures and a plurality of second conductive structures, wherein the first film layer comprises a plurality of first openings, and the first conductive structures are respectively located in the first openings and respectively cover inner walls of the first openings, the first film layer and the first conductive structures define the second lower surface, the third circuit layer is located on the first film layer and connected to the first conductive structures, and the first conductive structures electrically connect the first circuit layer with the third circuit layer; wherein the at least one fourth circuit layer is located on the at least one second film layer, the at least one second film layer comprises a plurality of second openings, the second conductive structures are respectively located in the second openings, respectively cover inner walls of the second openings, and electrically connects the third circuit layer with the at least one fourth circuit layer and the at least one fourth circuit layer with the fifth circuit layer; and wherein the third film layer has the second upper surface and comprises a plurality of third openings, and the third openings expose a portion of the fifth circuit layer and define the solder ball pads.

6. The package carrier as described in claim 1, wherein a size of each of the chip pads is smaller than a size of each of the solder ball pads.

7. The package carrier as described in claim 1, wherein the photoimageable dielectric layers each have a plurality of openings, and the conductive through holes respectively fill the openings and are connected to the first redistribution circuits.

8. The package carrier as described in claim 1, wherein an extension direction of each of the conductive through holes is opposite to an extension direction of each of the conductive structures.

9. The package carrier as described in claim 1, wherein a thickness of the first redistribution layer is smaller than a thickness of the second redistribution layer.

10. A manufacturing method of a package carrier, comprising:
forming two first redistribution circuit units, each of the first redistribution circuit units comprising a first carrier, a first redistribution layer, and a protective layer, wherein the first redistribution layer is located between the first carrier and the protective layer, and has a first upper surface and a first lower surface opposite to each other, and the first redistribution layer comprises a plurality of first redistribution circuits, a plurality of conductive through holes, a plurality of photoimageable dielectric layers, and a plurality of chip pads, wherein the first redistribution circuits are alternately stacked with the photoimageable dielectric layers, the conductive through holes electrically connect adjacent two of the first redistribution circuits, the chip pads are located on the first lower surface and are electrically connected to the first redistribution circuits through the conductive through holes, the first upper surface is in direct contact with the first carrier, and the protective layer covers the first lower surface and the chip pads;
providing a second carrier between the two first redistribution circuit units, wherein the second carrier is in direct contact with the protective layer of each of the first redistribution circuit units;
removing the first carrier and exposing the first upper surface of the first redistribution layer in each of the first redistribution circuit units;
forming a second redistribution layer on the first upper surface of each of the first redistribution layers, the second redistribution layer having a second upper surface and a second lower surface opposite to each other, and comprising a plurality of second redistribution circuits, a plurality of conductive structures, a plurality of Ajinomoto build-up film layers, and a plurality of solder ball pads, wherein the second redistribution circuits are alternately stacked with the Ajinomoto build-up film layers, the conductive structures electrically connect adjacent two of the second redistribution circuits and a closest one of the first redistribution circuits to the second redistribution circuits, and one of the Ajinomoto build-up film layers has the second upper surface and exposes the solder ball pads, wherein the second lower surface of the second redistribution layer is aligned with and directly connected to the first upper surface of the first redistribution layer, and a line width and a line pitch of each of the first redistribution circuits are smaller than a line width and a line pitch of each of the second redistribution circuits; and
removing the second carrier and the protective layer of each of the first redistribution circuit units, and exposing the first lower surface and the chip pads of the first redistribution layer.

11. The manufacturing method as described in claim 10, wherein the step of forming each of the first redistribution circuit units comprises:
forming the first redistribution layer on the first carrier, wherein the first carrier comprises a glass substrate, a sacrificial layer, and a seed layer, the sacrificial layer is located between the glass substrate and the seed layer, and the first upper surface of the first redistribution layer is in direct contact with the seed layer; and
forming the protective layer on the first lower surface of the first redistribution layer, wherein the protective layer covers the chip pads.

12. The manufacturing method as described in claim 10, wherein the second carrier comprises a substrate and two double-sided adhesive layers located on two opposite sides of the substrate, and each of the double-sided adhesive layers is located between the substrate and the protective layer of each of the redistribution circuit units.

13. The manufacturing method as described in claim 10, wherein the first redistribution circuits further comprise a first circuit layer and a plurality of second circuit layers, and the photoimageable dielectric layers comprise a first dielectric layer, at least one second dielectric layer, and a third dielectric layer, wherein the first dielectric layer covers the first circuit layer, the first dielectric layer and the first circuit layer define the first upper surface, the at least one second dielectric layer and the third dielectric layer cover the second circuit layers, the chip pads are located on the third dielectric layer, and the third dielectric layer has the first lower surface.

14. The manufacturing method as described in claim 13, wherein the second redistribution circuits comprise a third circuit layer, at least one fourth circuit layer, and a fifth circuit layer, the Ajinomoto build-up film layers comprise a first film layer, at least one second film layer, and a third film layer, and the conductive structures comprise a plurality of first conductive structures and a plurality of second conductive structures, wherein the first film layer comprises a plurality of first openings, and the first conductive structures are respectively located in the first openings and respectively cover inner walls of the first openings, the first film layer and the first conductive structures define the second lower surface, the third circuit layer is located on the first film layer and connected to the first conductive structures, and the first conductive structures electrically connect the first circuit layer with the third circuit layer; wherein the at least one fourth circuit layer is located on the at least one second film layer, the at least one second film layer comprises a plurality of second openings, the second conductive structures are respectively located in the second openings, respectively cover inner walls of the second openings, and electrically connects the third circuit layer with the at least one fourth circuit layer and the at least one fourth circuit layer with the fifth circuit layer; and wherein the third film layer has the second upper surface and comprises a plurality of third openings, and the third openings expose a portion of the fifth circuit layer and define the solder ball pads.

15. The manufacturing method as described in claim 10, wherein the line width and the line pitch of each of the first redistribution circuits each range from 2 μm to 10 μm.

16. The manufacturing method as described in claim 10, wherein the line width and the line pitch of each of the second redistribution circuits each range from 15 μm to 35 μm.

17. The manufacturing method as described in claim 10, wherein a size of each of the chip pads is smaller than a size of each of the solder ball pads.

18. The manufacturing method as described in claim 10, wherein an extension direction of each of the conductive through holes is opposite to an extension direction of each of the conductive structures.

19. The manufacturing method as described in claim 10, wherein each of the second redistribution circuits is formed at the same time with each of the conductive structures.

20. The manufacturing method as described in claim 10, wherein a thickness of the first redistribution layer is smaller than a thickness of the second redistribution layer.
